(19) United States
(12) Patent Application Publication
(10) Pub. No.: US 2022/0310150 A1
(43) Pub. Date: Sep. 29, 2022

(54) ELECTRONIC APPARATUS

(71) Applicant: KYOCERA Document Solutions Inc., Osaka (JP)

(72) Inventor: Satoshi Morimoto, Osaka (JP)

(21) Appl. No.: 17/701,199

(22) Filed: Mar. 22, 2022

(30) Foreign Application Priority Data
Mar. 29, 2021 (JP) 2021-056254

(51) Int. Cl. G11C 11/4074

(52) U.S. Cl. CPC G11C 11/4074

(57) ABSTRACT

An electronic apparatus includes a DRAM; an integrated circuit that includes a memory controller for the DRAM, a power-supply control circuit that controls a power-supply voltage of the DRAM or the integrated circuit, and a setting processing unit. Further, the setting processing unit determines an aperture width of an eye pattern of a signal between the DRAM and the memory controller, determines an aperture-width difference between the determined aperture width and a predetermined lowermost aperture width at one of end sides of the lowermost aperture width and an aperture-width difference between the determined aperture width and the lowermost aperture width at the other of the end sides of the lowermost aperture width, and decreases and determines the voltage value in accordance with the smaller one among the aperture-width differences.

### CROSS-REFERENCE TO RELATED APPLICATIONS

This application relates to and claims priority rights from Japanese Patent Application No. 2021-056254, filed on Mar. 29, 2021, the entire disclosures of which are hereby incorporated by reference herein.

### BACKGROUND

### 1. Field of the Present Disclosure

The present disclosure relates to an electronic apparatus.

### 2. Description of the Related Art

In general, in an electronic apparatus, a low power-supply voltage of an internal device such as integrated circuit or DRAM (Dynamic Random Access Memory) results in small electric power consumption.

An electronic apparatus repeatedly decreases the power-supply voltage from an initial value by a constant step width and performs a verification operation every time that the power-supply voltage is decreased, and thereby determines a lowest operable power-supply voltage.

However, long time is required to set the power-supply voltage because the power-supply voltage is repeatedly decreased by a constant step width and the verification operation is operated every time that the power-supply voltage is decreased, as mentioned.

### SUMMARY

An electronic apparatus according to an aspect of the present disclosure includes a DRAM, an integrated circuit that includes a memory controller for the DRAM, a power-supply control circuit configured to control a power-supply voltage of the DRAM or the integrated circuit, and a setting processing unit configured to set a voltage value of the power-supply voltage. Further, the setting processing unit (a) determines an aperture width of an eye pattern of a signal between the DRAM and the memory controller, (b) determines (b1) an aperture-width difference between the determined aperture width and a predetermined lowermost aperture width at one of end sides of the predetermined lowermost aperture width and (b2) an aperture-width difference between the determined aperture width and a predetermined lowermost aperture width at the other of the end sides of the predetermined lowermost aperture width, and (c) decreases and determines the voltage value in accordance with one of the aperture-width differences smaller than the other.

These and other objects, features and advantages of the present disclosure will become more apparent upon reading of the following detailed description along with the accompanied drawings.

### BRIEF DESCRIPTION OF THE DRAWINGS

FIG. 1 shows a block diagram that indicates a configuration of an electronic apparatus according to an embodiment of the present disclosure;

FIG. 2 shows a diagram that explains aperture-width differences of an eye pattern; and

FIG. 3 shows a flow chart that explains an initialization process for the electronic apparatus shown in FIG. 1.

### DETAILED DESCRIPTION

Hereinafter, an embodiment according to an aspect of the present disclosure will be explained with reference to drawings.

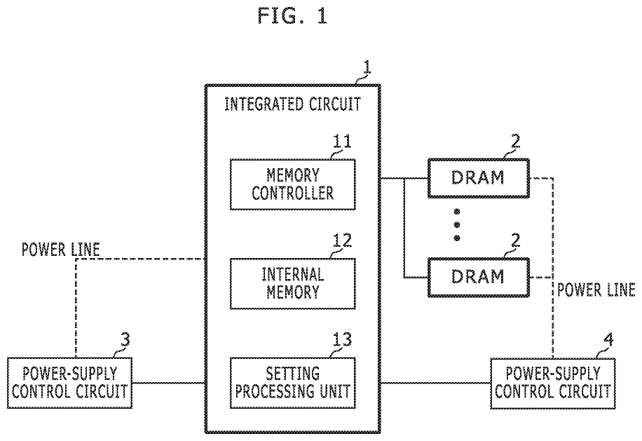

FIG. 1 shows a block diagram that indicates a configuration of an electronic apparatus according to an embodiment of the present disclosure. The electronic apparatus shown in FIG. 1 includes an integrated circuit 1, plural DRAMs 2, a power-supply control circuit 3 that controls a power-supply voltage of the integrated circuit 1, and a power-supply control circuit 4 that controls a power-supply voltage of the DRAMs 2.

The integrated circuit 1 is a chip that includes a built-in memory controller 11, a built-in nonvolatile internal memory 12, and a built-in setting processing unit 13.

The memory controller 11 is connected to the DRAMs 2 through a signal line such as memory bus, and transmits and receives a bus signal or the like to/from the DRAMs 2 and thereby performs data writing and data reading to/from the DRAMs 2.

The internal memory 12 stores a table or a relationship formula mentioned below, a voltage value of the power-supply voltage, and a setting value such as respective latency amounts of the DRAMs 2.

The setting processing unit 13 sets one or both (here, both) of voltage values of power-supply voltages of the integrated circuit 1 and the DRAMs 2.

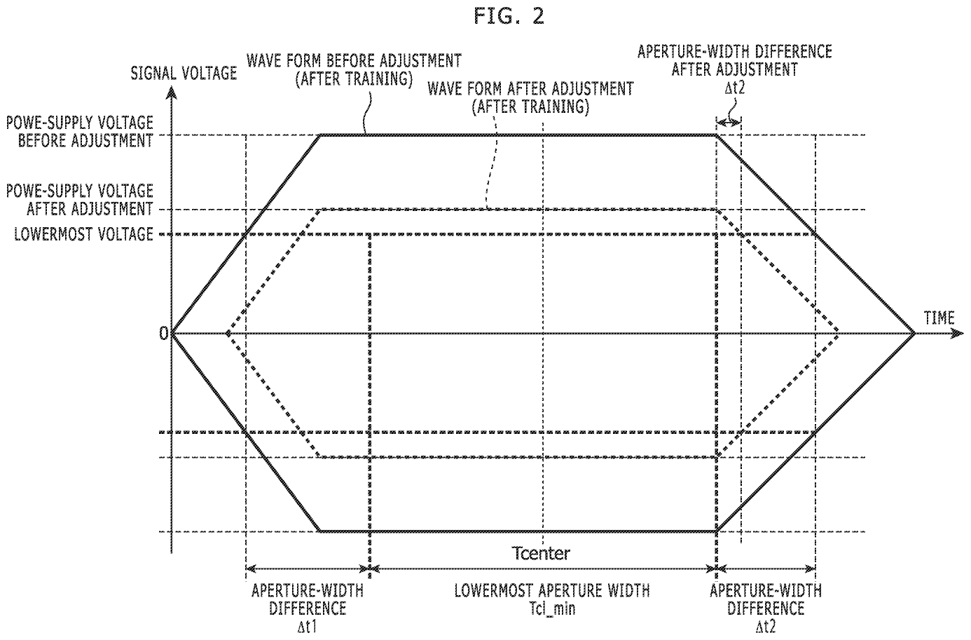

FIG. 2 shows a diagram that explains aperture-width differences of an eye pattern.

Specifically, as shown in FIG. 2, for example, the setting processing unit 13 (a) determines an aperture width of an eye pattern of a signal between the DRAMs 2 and the memory controller 11, (b) determines (b1) an aperture-width difference Δt1 between the determined aperture width and a predetermined lowermost aperture width Tcl_min at one of end sides of the predetermined lowermost aperture width Tcl_min and (b2) an aperture-width difference Δt2 between the determined aperture width and a predetermined lowermost aperture width Tcl_min at the other of the end sides of the predetermined lowermost aperture width Tcl_min, and (c) decreases and determines the voltage value in accordance with one (aperture-width difference Δts) of the aperture-width differences smaller than the other among the aperture-width differences Δt1 and Δt2.

For example, if an eye pattern (solid line FIG. 2) is acquired as shown in FIG. 2 and the lowermost aperture width Tcl_min has been set, then it is determined that the smaller aperture-width difference Δts is the aperture-width difference Δt2, a power-supply voltage value corresponding to a value of the aperture-width difference Δts (i.e. a value of the aperture-width difference Δt2) is determined on the basis of the table or the like, an eye pattern (broken line in FIG. 2) is acquired at the determined power-supply voltage value; and if in this eye pattern the aperture-width difference Δts (i.e. the aperture-width difference Δt2) exceeds a predetermined threshold value, then this power-supply voltage value is set.

It should be noted that the lowermost aperture width Tcl_min is set so as to have a predetermined time length with a predetermined center time point Tcenter.

Further, the power-supply voltage value of the DRAMs 2 may be set on the basis of a signal from the DRAMs 2 to the memory controller 11 and the power-supply voltage value of the integrated circuit 1 may be set on the basis of a signal from the memory controller 11 to the DRAMs 2; and otherwise, one of these power-supply voltage values may be set on the basis of one of these signals and the other of these power-supply voltage values may be set on the basis of the set power-supply voltage value.

Further, after determining the voltage value, the setting processing unit 13 (a) determines an aperture width of the eye pattern and determines the aperture-width difference Δts corresponding to this aperture width, and (b1) sets the determined voltage value if this aperture-width difference Δts exceeds a predetermined threshold value or (b2) determines the voltage value again after increasing or decreasing the voltage value of the power-supply voltage in accordance with the one of the aperture-width differences smaller than the other if this aperture-width difference Δts does not exceed the predetermined threshold value.

In this embodiment, the setting processing unit 13 includes a table or a relationship formula that indicates a relationship between the aperture-width difference Δts and the voltage value of the power-supply voltage, and determines the voltage value using the table or the relationship formula.

Each voltage value of the power-supply voltage in the table or the relationship formula takes a value corresponding to a value of the aperture-width difference Δts in a range from a predetermined minimum value (a lowermost power-supply voltage corresponding to the lowermost aperture width Tcl_min) to a predetermined maximum value (an uppermost power-supply voltage corresponding to an uppermost aperture width Tcl_max). The voltage value (and the aforementioned range) of the power-supply voltage of the integrated circuit 1 may be same as or different from the voltage value (and the aforementioned range) of the power-supply voltage of the DRAMs 2.

Further, the setting processing unit 13 determines and sets the voltage value with initialization of the integrated circuit 1 and the DRAMs 2.

Further, in this embodiment, in the initialization process, the setting processing unit 13 performs memory training for the plural DRAMs 2 and thereby determines the eye pattern, and saves the determined voltage value and a result (i.e. a signal latency amount on each of the DRAMs 2) of the memory training into the internal memory 12; and after the initialization process, the memory controller 11 operates in accordance with the saved result of the memory training, and the power-supply control circuits 3 and 4 control the aforementioned power-supply voltages such that the power-supply voltages get the saved voltage values, respectively.

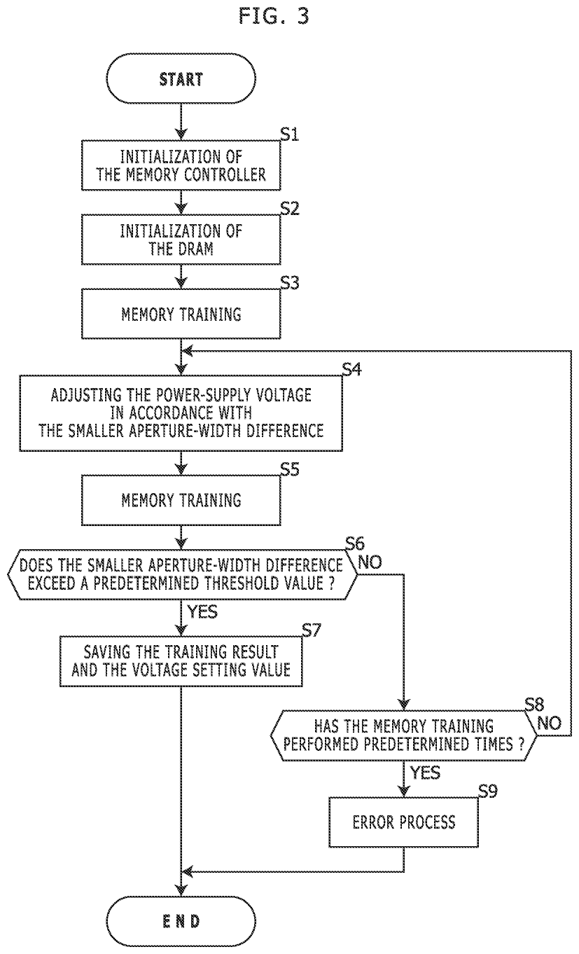

The following part explains the aforementioned electronic apparatus. FIG. 3 shows a flow chart that explains an initialization process for the electronic apparatus shown in FIG. 1.

When this electronic apparatus starts, the initialization process shown in FIG. 3 is performed.

In the initialization process, initialization of the memory controller 11 and the DRAMs 2 is firstly performed, and thereby the power-supply voltages are set as initial values (in Steps S1 and S2).

Afterward, the memory controller 11 performs memory training for the DRAMs 2 (in Step S3).

The setting processing unit 13 determines an eye pattern of a signal after the memory training, determines the aforementioned aperture-width differences Δt1 and Δt2, determines the smaller aperture-width difference Δts (i.e. one of Δt1 and Δt2 which can miss a requirement of the lowermost aperture width Tcl_min more easily than the other), determines voltage values corresponding to the aperture-width difference Δts (values smaller than the initial values), sets the determined voltage values to the power-supply control circuits 3 and 4, and causes the memory controller 11 to perform memory training for the DRAMs 2 with these voltage values (in Step S5).

Subsequently, the setting processing unit 13 determines an eye pattern after the memory training in Step S5, determines the aforementioned aperture-width differences Δt1 and Δt2 of this eye pattern, determines the smaller aperture-width difference Δts of this eye pattern, and determines whether this aperture-width difference Δts exceeds a predetermined threshold value (here, a value which provides a predetermined margin from the aforementioned lowermost aperture width to the aperture width) or not (in Step S6).

If the aperture-width difference Δts exceeds the predetermined threshold value, then the setting processing unit 13 determines that the voltage value set in Step S4 is proper, and saves this voltage value with the result of the memory training (in Step S7).

Otherwise, if the aperture-width difference Δts does not exceed the predetermined threshold value, then the setting processing unit 13 determines whether the number of times of the memory training (i.e. the number of times of setting the voltage value(s)) reaches a predetermined number of times (e.g. twice or three times) or not (in Step S8).

If the number of times of the memory training (i.e. the number of times of setting the voltage value(s)) does not reach the predetermined number of times, then the setting processing unit 13 returns to Step S4 and performs Step S4 and its subsequent processes as well, and sets the voltage value again.

Otherwise, if the number of times of the memory training (i.e. the number of times of setting the voltage value(s)) reaches the predetermined number of times, then the setting processing unit 13 performs an error process (in Step S9), and terminates this initialization process. In the error process, for example, the setting processing unit 13 displays on an unshown display device a message indicating that setting of power-supply voltages was failed. In this case, the setting processing unit 13 may set the power-supply voltage as the initial value and allow operation of this electronic apparatus or may prohibit operation of this electronic apparatus.

As mentioned, in the aforementioned embodiment, the setting processing unit 13 (a) determines an aperture width of an eye pattern of a signal between the DRAMs 2 and the memory controller 11, (b) determines (b1) an aperture-width difference Δt1 between the determined aperture width and a predetermined lowermost aperture width Tcl_min at one of end sides of the predetermined lowermost aperture width Tcl_min and (b2) an aperture-width difference Δt2 between the determined aperture width and a predetermined lowermost aperture width Tcl_min at the other of the end sides of the predetermined lowermost aperture width Tcl_min, and (c) decreases and determines the voltage value in accordance with one (aperture-width difference Δts) of the aperture-width differences smaller than the other among the aperture-width differences Δt1 and Δt2.

Consequently, the power-supply voltage value is set in accordance with one of Δt1 and Δt2 that has a smaller margin from the lowermost aperture width Tcl_min than the other, and therefore, performing the setting of the power-supply voltage value once or a few times provides a properly low power-supply voltage with satisfying a requirement of the lowermost aperture width Tcl_min. Thus, a proper power-supply voltage is set in relatively short time.

It should be understood that various changes and modifications to the embodiments described herein will be apparent to those skilled in the art. Such changes and modifications may be made without departing from the spirit and scope of the present subject matter and without diminishing its intended advantages. It is therefore intended that such changes and modifications be covered by the appended claims.

What is claimed is:

1. An electronic apparatus, comprising:
a DRAM;
an integrated circuit that comprises a memory controller for the DRAM;
a power-supply control circuit configured to control a power-supply voltage of the DRAM or the integrated circuit; and
a setting processing unit configured to set a voltage value of the power-supply voltage;
wherein the setting processing unit (a) determines an aperture width of an eye pattern of a signal between the DRAM and the memory controller, (b) determines (b1) an aperture-width difference between the determined aperture width and a predetermined lowermost aperture width at one of end sides of the predetermined lowermost aperture width and (b2) an aperture-width difference between the determined aperture width and a predetermined lowermost aperture width at the other of the end sides of the predetermined lowermost aperture width, and (c) decreases and determines the voltage value in accordance with one of the aperture-width differences smaller than the other.

2. The electronic apparatus according to claim 1, wherein after determining the voltage value, the setting processing unit (a) determines an aperture width of the eye pattern, and (b1) sets the determined voltage value if the one of the aperture-width differences smaller than the other exceeds a predetermined threshold value or (b2) determines the voltage value again after increasing or decreasing the voltage value of the power-supply voltage in accordance with the one of the aperture-width differences smaller than the other if the one of the aperture-width differences smaller than the other does not exceed the predetermined threshold value.

3. The electronic apparatus according to claim 1, wherein the setting processing unit comprises a table or a relationship formula that indicates a relationship between the one of the aperture-width differences smaller than the other and the voltage value of the power-supply voltage, and determines the voltage value using the table or the relationship formula.

4. The electronic apparatus according to claim 1, further comprising plural DRAMs that includes the DRAM;
wherein the setting processing unit performs memory training for the plural DRAMs and thereby determines the eye pattern, and saves the determined voltage value and a result of the memory training;
the memory controller operates in accordance with the saved result of the memory training; and
the power-supply control circuit controls the power-supply voltage such that the power-supply voltage gets the saved voltage value.

5. The electronic apparatus according to claim 1, wherein the setting processing unit is built in the integrated circuit.

6. The electronic apparatus according to claim 1, wherein the setting processing unit determines and sets the voltage value with initialization of the integrated circuit and the DRAM.
